(19) United States
(12) Patent Application Publication
(10) Pub. No.: US 2026/0078523 A1
(43) Pub. Date: Mar. 19, 2026

(54) METHOD OF GROWING GROUP III NITRIDE SINGLE CRYSTAL, JIG FOR USE IN GROWING GROUP III NITRIDE SINGLE CRYSTAL, AND APPARATUS FOR MANUFACTURING GROUP III NITRIDE SINGLE CRYSTAL

(71) Applicant: TOYODA GOSEI CO., LTD., Kiyosu-shi (JP)

(72) Inventors: Taku FUJIMORI, Kiyosu-shi (JP); Miki MORIYAMA, Kiyosu-shi (JP); Seiji NAGAI, Kiyosu-shi (JP); Yasuo IWATA, Kiyosu-shi (JP)

(21) Appl. No.: 19/280,868

(22) Filed: Jul. 25, 2025

(30) Foreign Application Priority Data
Sep. 17, 2024 (JP) 2024-159685
Sep. 27, 2024 (JP) 2024-168819

(51) Int. Cl. C30B 19/06; C30B 19/02; C30B 19/12; C30B 29/40

(52) U.S. Cl. CPC C30B 19/062; C30B 19/02; C30B 19/12; C30B 29/406

(57) ABSTRACT

A method of growing a group III nitride single crystal, including steps of forming a plurality of initial nuclei on a seed substrate having seed crystals made of a group III nitride single crystal formed thereon by immersing the substrate into a mixed melt in a crucible; forming a planarized crystal surface by immersing into a mixed melt in a crucible and pulling up therefrom to heat the substrate; and forming a thickened group III nitride single crystal on the seed substrate. When forming the plurality of initial nuclei, a concentration of alkali metals or alkaline earth metals other than Na in the mixed melt is set to 0.001 mol % or less, and when forming the thickened group III nitride single crystal, a concentration of alkali metals or alkaline earth metals other than Na in the mixed melt is set higher than that when forming the plurality of initial nuclei.

### CROSS-REFERENCE

This application claims priorities to Japanese Patent Application Nos. 2024-159685 filed on Sep. 17, 2024, and 2024-168819 filed on Sep. 27, 2024, the contents of which are fully incorporated herein by reference.

### BACKGROUND

### Technical Field

The present disclosure relates to a method of growing a group III nitride single crystal, a jig for use in growing a group III nitride single crystal, and an apparatus for manufacturing a group III nitride single crystal.

### Background Art

In the past, a flux method, in which a GaN substrate is immersed in a Ga-Na melt, i.e. a mixed melt of Ga and Na to grow GaN single crystals on the GaN substrate to form thickened GaN single crystals has been known. In this method, three-dimensional growth of GaN single crystals causes crystal growth so as to form large steps (macrosteps) on the order of several to several hundred micrometers, called macrostep growth. In a growth region of the macrosteps, clumps of Ga-Na melt, called inclusions, are formed in the crystal, which reduces crystal quality.

In order to reduce the inclusions thus formed, JP-A-2019-019040 discloses a method of forming thickened GaN single crystals on a GaN substrate by repeatedly performing a process in which the GaN substrate is immersed in a Ga-Na melt and then is heated under a nitrogen atmosphere while an alkaline earth metal such as Ca is added to the Ga-Na melt in advance to improve the wettability of the Ga-Na melt to the GaN substrate. In this method, macrostep growth is prevented, and the formation of inclusions is prevented accordingly, which leads to improvement in crystal quality.

### SUMMARY OF THE INVENTION

However, in the configuration disclosed in JP-A-2019-019040, when performing a process of forming initial nuclei of GaN single crystals on a substrate using a crucible in which the above Ga-Na melt is stored, miscellaneous crystals other than GaN single crystals are generated in a large amount due to high content of alkaline earth metals such as Ca, which makes it difficult to form an intended initial nucleus, resulting in a significant decrease in crystal quality.

The present disclosure has been made in view of the above and aims to provide a method of growing a group III nitride single crystal, a jig for use in growing a group III nitride single crystal, and an apparatus for manufacturing a group III nitride single crystal, which can improve crystal quality.

One aspect of this disclosure is a method of growing a group III nitride single crystal, the method comprising:
immersing a seed substrate, on which a plurality of seed crystals each made of a group III nitride single crystal is formed, into a mixed melt including a group III metal and Na and stored in a crucible to grow a group III nitride single crystal from each seed crystal to thereby form a plurality of initial nuclei;
repeatedly performing a process in which the seed substrate having the plurality of initial nuclei formed thereon is immersed into a mixed melt stored in a crucible and is pulled up from the crucible after the immersion and heated under a nitrogen atmosphere to grow the group III nitride single crystal from the initial nuclei and fill a gap between the initial nuclei adjacent to each other with the group III nitride single crystal to thereby form a planarized crystal surface; and
immersing the seed substrate having the planarized crystal surface into a mixed melt stored in a crucible to thereby form a thickened group III nitride single crystal on the seed substrate, wherein
when forming the plurality of initial nuclei, a concentration of alkali metals or alkaline earth metals other than Na in the mixed melt is set to 0.001 mol % or less, and
when forming the thickened group III nitride single crystal, a concentration of alkali metals or alkaline earth metals other than Na in the mixed melt is set higher than that when forming the plurality of initial nuclei.

Another aspect of this disclosure is a jig for use in growing a group III nitride single crystal, configured to support a substrate for growing the group III nitride single crystal inside a crucible, the jig comprising:
a substrate supporting part configured to support the substrate and immerse the substrate into a mixed melt including a group III metal and Na and stored in a crucible; and
an addition feeding part configured to add alkali metals or alkaline earth metals other than Na into the mixed melt when the substrate is immersed in the mixed melt, wherein
a first state in which the substrate supported by the substrate supporting part is immersed into the mixed melt but the addition feeding part is not immersed and a second state in which the substrate supported by the substrate supporting part and the addition feeding part are both immersed into the mixed melt can be switched to each other.

Another aspect of this disclosure is an apparatus for manufacturing a group III nitride single crystal, in which the group III nitride single crystal is grown on a seed substrate by supplying a gas containing nitrogen into a mixed melt including a group III metal and a flux, the apparatus comprising:
a plurality of jigs for holding the seed substrate to immerse and pull up the seed substrate in and from the mixed melt, wherein
each of the plurality of jigs is independently configured to be able to immerse and pull up the seed substrate in and from the mixed melt.

In the method of growing a group III nitride single crystal according to the above-mentioned one aspect, no alkali metal nor alkaline earth metal other than Na is included in the mixed melt when forming the plurality of initial nuclei. Therefore, the generation of miscellaneous crystals is curtailed when forming the plurality of initial nuclei, and the intended initial nuclei can be formed with high precision. And when forming the thickened group III nitride single crystal, any element(s) among alkali metals and alkaline earth metals other than Na is/are included in the mixed melt. There may be a case in which only Ca, as an alkaline earth metal, may be included in the mixed melt. This promotes the growth of group III nitride single crystals in the lateral direction from the initial nucleus, thereby curtailing the formation of macrosteps to prevent the formation of inclusions. Thus, the group III nitride single crystals thus formed can be improved in crystal quality.

The jig for use in growing a group III nitride single crystal according to another aspect mentioned above is configured so that the first state in which the substrate supported by the substrate supporting part is immersed into the mixed melt stored in the crucible but the addition feeding part is not immersed into the mixed melt and the second state in which the substrate supported by the substrate supporting part and the addition feeding part are both immersed into the mixed melt can be switched to each other. This makes it easy, when the substrate is immersed in the mixed melt, to set a state in which no alkali metal nor alkaline earth metal other than Na is added to the mixed melt when forming a plurality of initial nuclei, and to set a state in which alkali metals or alkaline earth metals other than Na is added to the mixed melt when forming the thickened group III nitride single crystal. As a result, the crystal quality of the formed group III nitride single crystal can be improved.

As described above, according to the above-mentioned aspect, a method of growing a group III nitride single crystal, a jig for use in growing a group III nitride single crystal, and an apparatus for manufacturing a group III nitride single crystal, which can improve the crystal quality, can be provided.

### BRIEF DESCRIPTION OF THE DRAWINGS

FIG. 1 a flowchart showing a method of growing a group III nitride single crystal in Embodiment 1.

FIG. 2 is a schematic diagram showing a state in which a seed substrate is immersed into a mixed melt and an alumina plate is not immersed thereinto in Embodiment 1.

FIG. 3 is a schematic diagram showing a state in which the seed substrate and the alumina plate are not immersed into the mixed melt in Embodiment 1.

FIG. 4 is a schematic diagram showing a state in which the seed substrate and the alumina plate are immersed into the mixed melt in Embodiment 1.

FIG. 5 is a top view of a jig and a crucible in Embodiment 1.

FIG. 6 is a schematic view of the seed substrate in Embodiment 1, in which (a) shows the seed substrate on which a plurality of seed crystals is formed, (b) shows the seed substrate on which a plurality of initial nuclei is formed, (c) shows a state in which a GaN single crystal is formed between each of the plurality of initial nuclei, and (d) shows a state in which the GaN single crystal is grown on a planarized crystal surface.

FIG. 7 is a plan view showing a configuration of the seed substrate in Embodiment 1.

FIG. 8 is a cross-sectional view showing a configuration of the seed crystal in Embodiment 1, of which the cross-section is perpendicular to the principal surface of the substrate.

FIG. 9 is a plan view showing the configuration of the seed crystal in Embodiment 1.

FIG. 10 is a schematic view illustrating a step of forming the initial nuclei in Modification 1 of Embodiment 1.

FIG. 11 is a schematic view illustrating a step of forming a thickened group III nitride single crystal in Modification 1 of Embodiment 1.

FIG. 12 is a schematic view illustrating a step of forming the initial nuclei in Modification 2 of Embodiment 1.

FIG. 13 is a schematic view illustrating a step of forming a thickened group III nitride single crystal in Modification 2 of Embodiment 1.

FIG. 14 is an illustration schematically showing transfer of the seed substrate to another crucible in Embodiment 2.

FIG. 15 is an illustration schematically showing a FFC method in a step of forming a planarized crystal surface.

FIG. 16 is a schematic view showing a configuration of a jig in an apparatus for manufacturing a group III nitride single crystal in Embodiment 2.

FIG. 17 is a plan view vertically viewed from above, showing the relation between the arrangement of first, second, and third crucibles and the arrangement of three jigs in Embodiment 2.

### DETAILED DESCRIPTION OF PREFERRED EMBODIMENTS

In the method of growing a group III nitride single crystal according to one aspect mentioned above, it is preferable that when forming the thickened group III nitride single crystal, a member containing alkali metals or alkaline earth metals other than Na is immersed into the mixed melt to thereby elute the alkali metals or alkaline earth metals other than Na from the member into the mixed melt, and that when forming the plurality of initial nuclei, the member containing alkali metals or alkaline earth metals other than Na is not immersed in the mixed melt. In this case, when forming the thickened group III nitride single crystal, it becomes easy to add a small amount of alkali metals or alkaline earth metals other than Na to the mixed melt.

In the method of growing a group III nitride single crystal according to the one aspect mentioned above, when forming the planarized crystal surface, a member containing alkali metals or alkaline earth metals other than Na may be immersed into the mixed melt to thereby elute the alkali metals or alkaline earth metals other than Na from the member into the mixed melt. In this case, the wettability of the mixed melt to the seed substrate when forming a planarized crystal surface can be improved to promote planarization of the crystal surface.

In the method of growing a group III nitride single crystal according to the one aspect mentioned above, when forming the planarized crystal surface, a member containing alkali metals or alkaline earth metals other than Na may be prevented from being immersed into the mixed melt. In this case, formation of miscellaneous crystals is prevented when forming the planarized crystal surface and crystal quality is improved.

In the method of growing a group III nitride single crystal according to the one aspect mentioned above, the member containing alkali metals or alkaline earth metals other than Na is preferably made of alumina containing alkali metals or alkaline earth metals other than Na. In this case, alkali metals or alkaline earth metals other than Na can be gently eluted by immersing the alumina member containing the alkali metal or alkaline earth metal other than Na into the mixed melt, so that it becomes easy to add a small amount of alkali metals or alkaline earth metals other than Na into the mixed melt in forming the thickened group III nitride single crystal.

In the method of growing a group III nitride single crystal according to the one aspect mentioned above, it is preferable that the seed substrate is supported by a jig and is configured to be immersed in the mixed melt and pulled up therefrom via the jig, and that the member containing alkali metals or alkaline earth metals other than Na constitutes part of the jig or is supported by the jig. In this case, the jig makes it easy to control whether or not to add the alkali metals or alkaline earth metals to the mixed metal.

In the method of growing a group III nitride single crystal according to the one aspect mentioned above, it is preferable that the alkali metals or alkaline earth metals other than Na are added to the mixed melt at a time after forming the plurality of initial nuclei and before forming the thickened group III nitride single crystal, or at a time of forming the thickened group III nitride single crystal. In this case, it becomes easy to prevent the mixed melt from containing the alkali metals or alkaline earth metals other than Na when forming the plurality of initial nuclei and to allow the mixed melt to contain the alkali metals or alkaline earth metals other than Na when forming the thickened group III nitride single crystal.

In the method of growing a group III nitride single crystal according to the one aspect mentioned above, it is preferable that when forming the thickened group III nitride single crystal, the alkali metals or alkaline earth metals other than Na is mixed in the mixed melt at a ratio of 0.01 mol % or more and less than 0.05 mol %. In this case, the ratio of the alkali metals or alkaline earth metals other than Na contained in the mixed melt in forming the thickened group III nitride single crystal is extremely low, thus the formation of inclusions can be prevented and at the same time the formation of miscellaneous crystals can be prevented.

In the method of growing a group III nitride single crystal according to the one aspect mentioned above, when forming the plurality of initial nuclei, a calcium concentration of the mixed melt may be adjusted to be 0.001 mol % or less by use of a first crucible made of alumina having a calcium concentration of 0.01 mol % or less to hold the mixed melt therein, and when forming the thickened group III nitride single crystal, the calcium concentration of the mixed melt may be adjusted to be higher than 0.001 mol % by use of a second crucible made of alumina having a calcium concentration higher than 0.01 mol % to hold the mixed melt therein.

In the method of growing a group III nitride single crystal according to the one aspect mentioned above, when forming the plurality of initial nuclei, the first crucible made of alumina having a calcium concentration of 0.01 mol % or less may be used to hold the mixed melt of which the calcium concentration is 0.001 mol % or less, and when forming the thickened group III nitride single crystal, the second crucible made of alumina may be used to hold the mixed melt of which the calcium concentration is higher than 0.001 mol %.

In the method of growing a group III nitride single crystal according to the one aspect mentioned above, when forming the planarized crystal surface, a calcium concentration of the mixed melt may be adjusted to be 0.001 mol % or higher by use of a third crucible made of alumina having a calcium concentration of 0.01 mol % or higher to hold the mixed melt therein, and when forming the thickened group III nitride single crystal, the calcium concentration of the mixed melt may be higher than that when forming the planarized crystal surface.

In the method of growing a group III nitride single crystal according to the one aspect mentioned above, when forming the planarized crystal surface, a third crucible made of alumina may be used to hold the mixed melt of which the calcium concentration is higher than 0.001 mol %, and when forming the thickened group III nitride single crystal, the calcium concentration of the mixed melt may be higher than that when forming the planarized crystal surface.

In the method of growing a group III nitride single crystal according to the one aspect mentioned above, when forming the planarized crystal surface, the second crucible may be used.

In the method of growing a group III nitride single crystal according to the one aspect mentioned above, when forming the thickened group III nitride single crystal, the calcium concentration of the mixed melt may be adjusted to be 0.001 mol % or higher by use of a fourth crucible made of alumina having a calcium concentration of 0.01 mol % or higher to hold the mixed melt therein, and after forming a planarized group III nitride single crystal using the second crucible, a further group III nitride single crystal may be formed using the fourth crucible.

In the method of growing a group III nitride single crystal according to the one aspect mentioned above, when forming the thickened group III nitride single crystal, a fourth crucible made of alumina may be used to hold the mixed melt of which the calcium concentration is higher than 0.001 mol %, and after forming a planarized group III nitride single crystal using the second crucible, a further group III nitride single crystal may be formed using the fourth crucible.

In the jig for use in growing a group III nitride single crystal according to another aspect mentioned above, the addition feeding part preferably holds a member including alkali metals or alkaline earth metals other than Na and to elute the alkali metals or alkaline earth metals other than Na from the member including the alkali metals or alkaline earth metals other than Na into the mixed melt in the second state. Such a configuration makes it easy to switch the first state in which no alkali metal nor alkaline earth metal other than Na is contained in the mixed melt and the second state in which the alkali metals or alkaline earth metals other than Na is contained in the mixed melt.

In the apparatus for manufacturing a group III nitride single crystal according to another aspect mentioned above, the jigs may be arranged at equal intervals on a circumference when vertically viewed from above, having a configuration to be rotatable integrally around a center of the circumference.

### Embodiment 1

### 1-1. Outline of Flux Method

The method of growing a group III nitride single crystal in Embodiment 1 is a method in which a group III nitride single crystal is grown by a flux method. Thus, a group III nitride semiconductor is manufactured. The flux method is a method in which a mixed melt containing an alkali metal that acts as a flux and a group III metal as a raw material is dissolved by supplying a gas containing nitrogen thereinto to thereby grow a group III nitride semiconductor epitaxially in the liquid phase.

In this embodiment, the mixed melt contains Na as an alkali metal that serves as a flux. The group III metal as a raw material is at least one of gallium (Ga), aluminum (Al), and indium (In), the ratio of which can control a composition of a group III nitride single crystal to be formed. For example, GaN, AlN, InN, AlGaN, InGaN, AlGaInN, etc. can be formed. This disclosure is particularly suitable for forming GaN, and Embodiment 1 is a method of growing a single crystal of GaN. This method uses Na as a flux, and is particularly referred to as a Na-flux method. The gas containing nitrogen is a gas of compounds that contain nitrogen as a constituent element, such as nitrogen molecules and ammonia. It can also be a mixture of those gases. Also, the nitrogen-containing gas may be mixed with an inert gas such as a noble gas.

Carbon (C) may be added to the mixed melt. The crystal grow rate can be increased by the addition of carbon. Any dopants other than C may also be added to the mixed melt to control properties such as the conduction type and magnetism of a group III nitride semiconductor to be crystal-grown, to promote crystal growth, to reduce miscrystallization, to control the growth direction, and so on.

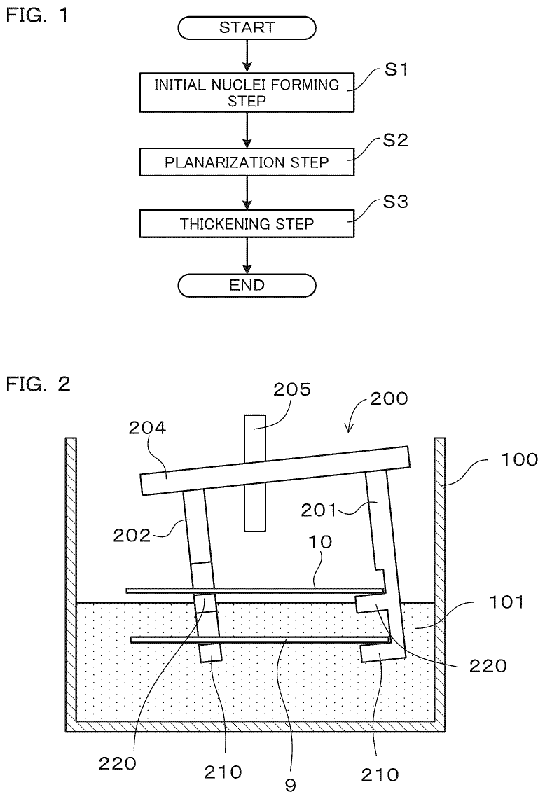

The method of growing a group III nitride single crystal in Embodiment 1 includes an initial nuclei forming step S1, a planarization step S2, and a thickening step S3, as shown in FIG. 1. In the initial nuclei forming step S1, the mixed melt contains no alkali metal nor alkaline earth metal other than Na. Here, what is meant by “no alkali metal nor alkaline earth metal other than Na” means that the concentration of alkali metals or alkaline earth metals other than Na is 0 mol %. In the initial nuclei forming step S1, the concentration of the alkali metals or alkaline earth metals other than Na may be 0.001 mol %. In the meantime, in the thickening step S3, the concentration of alkali metals or alkaline earth metals other than Na is set to be higher than that in the initial nuclei forming step S1. In the case where no alkali metal nor alkaline earth metal other than Na is contained in the initial nuclei forming step S1, alkali metals or alkaline earth metals other than Na is contained in the thickening step S3. As an alkali metal other than Na, Li can be employed. Ca, Ba, Mg, or Sr can be employed as an alkaline earth metal. The content ratio of the alkali metals or alkaline earth metals other than Na in the mixed melt in thickening step S3 may be set to less than 0.05 mol %, and in this embodiment 1, it is set to 0.01 mol % or more and 0.05 mol % or less. The steps S1 to S3 each will be described in detail later.

### 1-2. Jig for Use in Growing a Group III Nitride Single Crystal

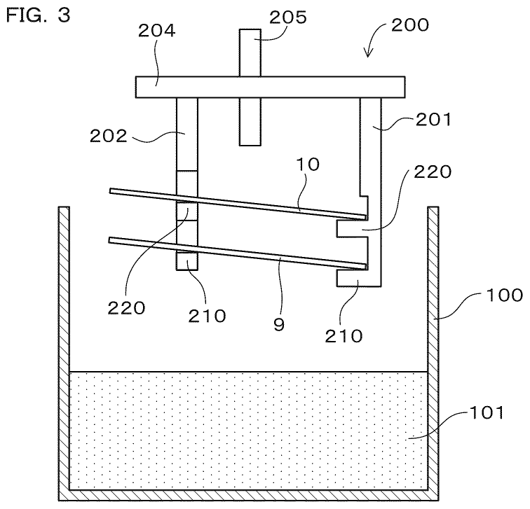

A jig 200 for use in growing a group III nitride single crystal in Embodiment 1 is placed inside a crucible 100 for growing semiconductor single crystals by the flux method, as shown in FIGS. 2 and 3. The jig 200 can support a seed substrate 9 for growing group III nitride semiconductor single crystals inside the crucible 100. The jig 200 has a first leg 201, a second leg 202, a third leg 203, a connecting portion 204, and an elevating shaft 205. The material of each component of the jig 200 is alumina. The first leg 201, the second leg 202, and the third leg 203 are formed in an abbreviated rod shape as shown in FIG. 2, and hang down respectively at the corners of the connecting portion 204 in the form of a flat plate almost triangular shaped in plan view as shown in FIG. 5.

At each lower end of the first leg 201, the second leg 202, and the third leg 203, a substrate support portion 210 having convexity that is capable of supporting the seed substrate 9 is formed. As shown in FIGS. 2 and 3, the first leg 201 is formed longer than the second leg 202 and the third leg 203. Thus, the substrate 1 supported by the substrate supporting part 210 is in an inclined position against the connecting portion 204. The connecting portion 204 is connected to the elevating shaft 205 so as to have a posture inclined with respect to an elevating rotary shaft 205. As a result, the substrate 1 supported by the substrate support portion 210 can be switched between the horizontal state shown in FIG. 2 and the inclined state shown in FIG. 3.

The first leg 201, the second leg 202, and the third leg 203 each have an addition feeding part 220 formed at a position vertically above the substrate supporting part 210. In Embodiment 1, the addition feeding part 220 forms a step to support an alumina plate 10 containing alkali metals or alkaline earth metals other than Na. In Embodiment 1, the alumina plate 10 contains Ca as an alkaline earth metal. The alumina plate 10 is supported parallel to the seed substrate 9 supported by the substrate supporting part 210.

### 1-3. Details of a Method of Growing a Group III Nitride Single Crystal

The method of growing a group III nitride single crystal in Embodiment 1 includes an initial nuclei forming step S1, a planarization step S2, and a thickening step S3, as shown in FIG. 1. Each step will be described in detail below. It is noted that in Embodiment 1, a method of growing a GaN single crystal as a group III nitride single crystal is described.

### 1-3-1. Initial Nuclei Forming Step S1

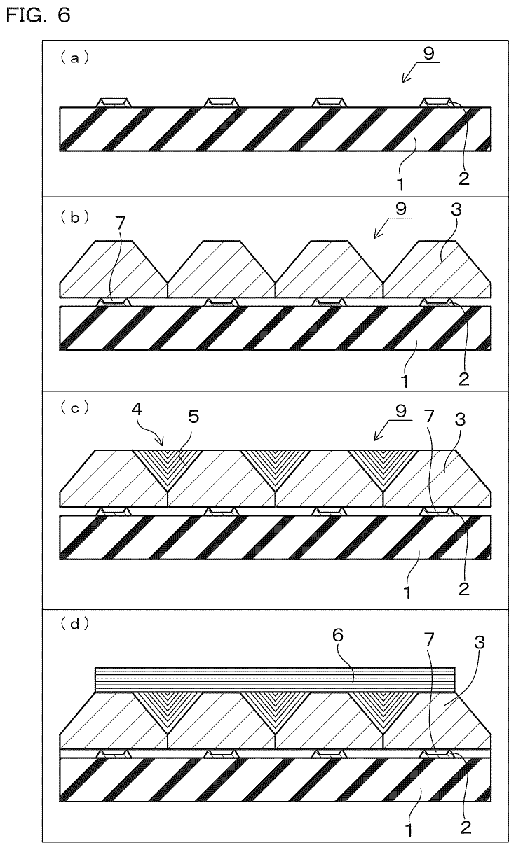

In the initial nuclei forming step S1, the seed substrate 9 (see (a) in FIG. 6), on which the plurality of seed crystals 2 each made of a GaN single crystal is formed, into a mixed melt 101 stored in the crucible to grow a GaN single crystal from each seed crystal to thereby form the plurality of initial nuclei 3.

In the initial nuclei forming step S1, first, as shown in FIG. 2, the substrate supporting part 210 of the jig 200, which is in the state of having the seed substrate 9 placed thereon, is immersed into the mixed melt 101 stored in the crucible 100. At this time, the seed substrate 9 is nearly horizontal. In this embodiment, although the alumina plate 10 is placed on the addition feeding part 220 of the jig 200, the alumina plate 10 is not immersed in the mixed melt 101 in the initial nuclei forming step S1. The seed substrate 9 is preferably put into the mixed melt after heated and pressurized to reach the growth temperature and pressure. This can prevent the seed crystals 2 on the seed substrate 9 from melting back.

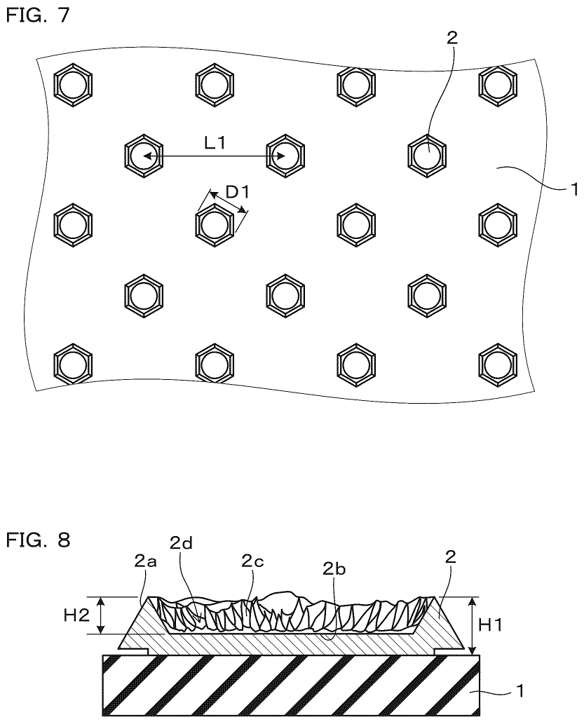

The seed substrate 9 is an MPS (multipoint seed) substrate. An MPS (multipoint seed) substrate is a substrate having a plurality of dotted seed crystals 2 periodically arranged on the substrate 1. FIG. 6 is a cross-sectional view of the seed substrate 9, of which the cross-section is perpendicular to the principal surface of the substrate. FIG. 7 is a plan view of the seed substrate 9 viewed from above.

A group III nitride semiconductor, sapphire, aluminum oxynitride, SiC, Si, spinel, ZnO, gallium oxide, etc. can be used for the substrate 1. In the case of a sapphire substrate, for example, the c-plane and a-plane are the principal surface of the substrate.

On the substrate 1, a plurality of seed crystals 2 is provided via a buffer layer (not shown). The seed crystals 2 are arranged in an equilateral triangular lattice pattern. The buffer layer and the seed crystals 2 are group III nitride semiconductors of any composition, such as GaN, AlGaN, and AlN. The material of the buffer layer is selected appropriately for the material of the seed crystal 2. For example, when the seed crystal 2 is GaN, the buffer layer is preferably GaN. The material of the seed crystal is usually a group III nitride semiconductor of the same composition as the group III nitride semiconductor to be grown by the flux method. The seed crystals 2 can be grown by any method, such as an MOCVD method, a HVPE method, an MBE method, etc. The MOCVD method and the HVPE method are preferable in terms of crystallinity and growth time.

The seed crystals 2 are arranged in an equilateral triangular lattice pattern as shown in FIG. 7. Not limited to the equilateral triangular lattice pattern, any periodic arrangement is acceptable, however, a highly symmetrical pattern such as a square lattice, an equilateral triangular lattice, etc. is preferred. Group III nitride semiconductors each grown from each seed crystal 2 can coalesce uniformly to grow the group III nitride semiconductors with fewer dislocations and less warpage. In the case of an equilateral triangular lattice pattern, it is preferable to match the arrangement direction with the a-axis and m-axis directions of the seed crystal 2. The term “match” here does not mean perfect match, but an angular misalignment of about 10 degrees is acceptable as an error. The angular misalignment is preferably 1 degree or less.

A distance L1 between the centers of the seed crystals 2 adjacent to each other is preferably 100 to 2000 μm. In this range, group III nitride semiconductors with fewer dislocations and warpage can be grown. More preferably, it is 200 to 1500 μm, and even more preferably 300 to 1000 μm.

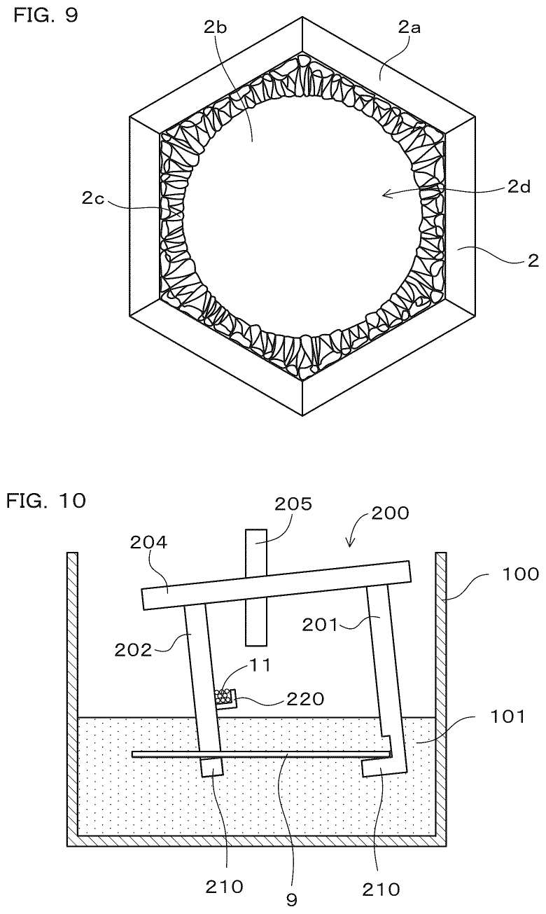

Next, the shape of the seed crystal 2 is explained in detail. FIG. 8 is a cross-sectional view showing the configuration of the seed crystal 2, of which the cross-section is perpendicular to the principal surface of the substrate. FIG. 9 is a plan view showing the configuration of the seed crystal 2. As shown in FIGS. 8 and 9, the seed crystal 2 has a shape including a disk portion shaped in a form of a circular disk and a truncated regular hexagonal pyramid portion located on the disk portion in contact therewith, shaped in a form of a truncated regular hexagonal pyramid and provided with a recess 2d at its center.

As described below, the seed crystal 2 is formed by selective growth using a mask with an opening, and through which the crystal is grown laterally. The opening of the mask has a circular pattern. Therefore, after the mask is removed, the opening of the mask patterns the substrate in a form of a circular disk. The patterned part corresponds to the disk portion. The disk portion has the same shape as the opening of the mask for selectively growing the seed crystal 2. A diameter D1 of the truncated regular hexagonal pyramid portion is larger than the diameter of the disk portion. The disk portion is circular in a plan view, and thus the stress caused when the substrate 1 is separated after GaN single crystals have been grown using the flux method can be dispersed to thereby curtail occurrence of any cracks in the grown crystal. Although the disk portion can be replaced with a regular hexagonal plate shaped in a form of a regular hexagon or otherwise by changing the opening pattern of the mask, a circular form of the disk portion is preferred as it disperses stress as described above.

The bottom surface of the truncated regular hexagonal pyramid portion of the seed crystal has a shape of a regular hexagon. In particular, a regular hexagon with each side aligned with the m-plane of the seed crystal 2 (with each side aligned with the a-axis direction) is preferred because a group III nitride semiconductor is hexagonal, and a regular hexagon allows a group III nitride semiconductor grown from the truncated regular hexagonal pyramid portion of each seed crystal 2 to coalesce uniformly. However, it is not necessary for each side of the regular hexagon to be perfectly aligned with the a-axis, and an angular misalignment of about 10 degrees is acceptable. Preferably, the angular misalignment is 1 degree or less.

Each of the six outer peripheral surfaces 2a of the truncated regular hexagonal pyramid portion of the seed crystal 2 is the (10-11) plane of a group III nitride semiconductor. The (10-11) plane is stable in the mixed melt in the Na-flux method. Therefore, the initial nucleus 3, which will be described later, grows from the outer peripheral surface 2a of the truncated regular hexagonal pyramid portion of the seed crystal 2 while maintaining the (10-11) plane(s). As a result, the shape of the initial nucleus 3 can be uniformly shaped. The surface of the outer peripheral surface 2a need not be entirely a (10-11) surface, but at least 95% of the entire outer peripheral surface is preferably a (10-11) surface. It is noted that the (10-11) plane referred to here also includes a plane that forms an angle of −5 to 5 degrees with respect to the (10-11) plane as an error.

The diameter D1 (a diameter of the circumscribed circle in a plan view) of the truncated regular hexagonal pyramid portion of the seed crystal 2 is preferably 10 to 500 μm. In this range, a group III nitride semiconductor with fewer dislocations and warpage can be grown. In addition, the area of the outer peripheral surface 2a of the truncated regular hexagonal pyramid portion of the seed crystal 2 can be made larger to thereby facilitate the growth of an initial nucleus 3 from the outer peripheral surface 2a. The diameter D1 is more preferably 50 to 300 μm, and even more preferably 100 to 200 μm.

Additionally, a height H1 of the seed crystal 2 is preferably 30 μm or more. Within this range, the outer peripheral surface 2a can have a sufficiently wide area, which enables uniform crystal growth from the outer peripheral surface 2a. As a result, the shapes of the initial nuclei 3 growing from the seed crystals 2 can be uniformly shaped. However, if the H1 is excessively high, there is such a problem that it takes much time to form the seed crystals 2. Thus, the H1 is preferably set to 100 μm or less. More preferably, it is 20 to 60 μm, and even more preferably, 30 to 50 μm.

Furthermore, for the same reasons as above, the height H1 of the seed crystal 2 is preferably 0.01 to 0.6 times the diameter D1 of the seed crystal 2. More preferably, it is 0.1 to 0.35 times, and even more preferably, it is 0.15 to 0.3 times.

A recess 2d is provided at the center of the seed crystal 2. By providing the recess 2d, the initial nucleus 3 grown from the seed crystal 2 does not fill the recess 2d to form a void 7. The void 7 thus formed prevents dislocations in the seed crystal 2 from propagating upward, which enables growth of a high-quality a GaN single crystal.

The bottom surface 2b of the recess 2d is flat and corresponds to a (0001) plane (c-plane) of a group III nitride semiconductor. The bottom surface 2b is approximately circular when viewed in plan. It is noted that the bottom surface 2b does not necessarily need to be flat and may have irregularities. Additionally, the shape of the bottom surface 2b does not necessarily need to be circular when viewed in plan.

The side surface 2c of the recess 2d has a lot of irregularities formed thereon and wholly has the same level of inclination as that of the (10-11) plane. By shaping the side surface 2c to have such irregularities, the side surface 2c serves as a starting point for crystal growth of the group III nitride semiconductor to thereby make it easy to fill the upper portion of the seed crystal 2 with the group III nitride semiconductor. It is noted that the side surface 2c may also be a flat surface.

A depth H2 of the recess 2d is preferably 10 to 100 μm. Within this range, it becomes easier to form voids 7, and thus a higher-quality group III nitride semiconductors can be grown. More preferably, the depth H2 is 20 to 60 μm, and even more preferably, 30 to 50 μm. For the same reasons, the depth H2 of the recess 2d is preferably 0.3 to 1.0 times the height H1 of the seed crystal 2, and more preferably 0.6 to 0.8 times.

The diameter of the top surface of the recess 2d falls within the range such that the seed crystal 2 has no upper surface. The side surface 2c of the recess 2d and the outer peripheral surface 2a of the seed crystal 2 are connected at an angle. Therefore, there is no c-plane on the top of the seed crystal 2. C-plane may be melted back in the mixed melt in the Na-flux method, which is a factor of causing variation in the shape of each initial nucleus 3.

In addition, dislocations in the seed crystal 2 may be propagated upward by crystal growth from the c-plane. Therefore, if the top of the crystal is shaped to have no c-plane, variation in the shape of each initial nucleus 3 can be curtailed, and dislocation in the seed crystal 2 can be prevented from propagating upward.

In the initial nuclei forming step S1, the seed substrate 9 can be prepared, for example, as follows. First, a mask with a plurality of openings is formed on the substrate 1.

The openings are arranged in an equilateral triangular lattice pattern. The shape of each opening is a circle. Although shapes other than a circle, such as regular hexagons, are also acceptable, a circle is preferable as used in the embodiment in order to form a disc portion and curtail cracking caused when the substrate is separated. The material of the mask can be any material that can prevent a group III nitride semiconductor from growing on the mask, such as SiO₂.

Next, a buffer layer (not shown) and the seed crystal 2 are selectively grown on the substrate exposed to the opening in sequence by MOCVD, HVPE, or other methods. Next, the mask is removed by melt-back with hydrofluoric acid or the like. The seed substrate 9 can be prepared as described above.

Here, by appropriately controlling the growth conditions when selectively growing the seed crystal 2 through the opening of the mask, facet growth of a group III nitride semiconductors is made possible, so that the seed crystal 2 can be shaped as shown in FIG. 8 and FIG. 9. For example, the growth temperature may be 1120 to 1145° C. and the V/III ratio may be 970 to 1020. The seed crystals 2 can be uniformly shaped because the selective growth determines the shape of each seed crystal 2.

In this Embodiment 1, the initial nuclei forming step S1 can be performed as described below. First, the furnace atmosphere is replaced with an inert gas, the furnace is heated, and then vacuumed to sufficiently reduce outgas components in the furnace, such as oxygen.

Next, a predetermined amount of Na and Ga are weighed in a glove box in which the atmosphere, such as oxygen and dew point, is controlled. The weighed predetermined amount of Na and Ga are then fed into a crucible 100 (see FIG. 2). If necessary, additive elements such as carbon may be fed.

Next, the crucible 100 in which the raw materials are set and the seed substrate 9 are placed in a reaction vessel and evacuated, and then a gas containing nitrogen is supplied to the reaction vessel. Once the pressure in the reaction vessel reaches a crystal growth pressure, the furnace is heated to a crystal growth temperature. The crystal growth temperature is, for example, 700° C. or higher and 1000° C. or lower, and the crystal growth pressure is, for example, 2 MPa or higher and 10 MPa or lower. In the process of raising the temperature, the Na and Ga in the crucible 100 melt and turn into liquid, forming a mixed melt 101. In this stage, the seed substrate 9 is not yet put into the mixed melt 101.

When the temperature and pressure inside the reaction vessel reach the crystal growth temperature and the crystal growth pressure, and the nitrogen dissolved in the mixed melt 101 reaches supersaturation, the seed substrate 9 is put into the mixed melt 101 in the crucible 100. Thus, Gan crystals (initial nuclei 3) are grown respectively from the crystals 2 of the seed substrate 9. The initial nuclei 3 grow until the initial nuclei 3 adjacent to each other begin to coalesce with each other (see (b) in FIG. 6). It is noted that a gap remains between the initial nuclei 3 and the substrate 1.

Here, the (10-11) plane, which is the outer peripheral surface 2a of the truncated regular hexagonal pyramid portion of the seed crystal 2, is stable in the mixed melt 101 without being etched. In addition, the height H1 of the seed crystal 2 is 30 μm or more, and the outer peripheral surface 2a is sufficiently large in area. Therefore, the initial nucleus 3 grows from the outer peripheral surface 2a while maintaining the (10-11) plane.

Because the initial nucleus 3 grows from the seed crystal 2, which is uniformly shaped, while maintaining the (10-11) plane, variation in the shape of each initial nucleus 3 can be curtailed and the initial nuclei 3 can be uniformly shaped.

Because the recess 2d is formed in the center of the seed crystal 2, the initial nucleus 3 does not fill the recess 2d completely to form a void 7. The void 7 keeps in the mixed melt 101. Because the void 7 is formed at the upper part of the seed crystal 2, dislocations in the seed crystal 2 are prevented from being succeeded upward.

Furthermore, by setting the diameter of the recess 2d large, the seed crystal 2 is formed into a shape that has no upper surface (c-plane). The c-plane may be etched in the mixed melt 101 and is an unstable surface. Because crystal growth from such an unstable surface does not occur, variation in the shape of the initial nucleus 3 can be further curtailed. Additionally, because crystal growth from the c-plane does not occur, the transfer of dislocations from the seed crystal 2 to the upper part can be further curtailed.

### 1-3-2. Planarization Step S2

As shown in FIG. 1, a planarization step S2 is performed after the initial nuclei forming step S1. In the planarization step S2 in Embodiment 1, the crystal is grown using the FFC (flux film coating) method, in which a planarized crystal surface is formed by repeatedly performing a process in which the seed substrate 9 having the initial nuclei 3 formed thereon is immersed into the mixed melt stored in the crucible 100 and is pulled up therefrom and heated under a nitrogen atmosphere to grow the GaN single crystal from the initial nuclei 3 and fill a gap between the initial nuclei 3 adjacent to each other with GaN single crystal.

In the FFC method in the planarization step S2 in this Embodiment 1, a process, in which the seed substrate 9 is pulled up from the mixed melt 101 as shown in FIG. 3 and is immersed into the mixed melt 101 as shown in FIG. 2, is repeatedly performed at a predetermined cycle. As shown in (b) in FIG. 6, at the stage where the initial nuclei 3 adjacent to each other begin to coalesce with each other, the depression 4 is formed on the coalescent surfaces. When the seed substrate 9 is removed from the mixed melt 101, the mixed melt 101 accumulates in the depressions 4 between the adjacent initial nuclei 3. This allows a buried layer 5 to grow along the depressions 4 (see (c) in FIG. 6).

Here, because the mixed melt 101 accumulated in the depression 4 is thin in thickness, nitrogen tends to supersaturate. Thus, the crystal growth rate can be accelerated. However, because the amount of the accumulated mixed melt 101 is small, the amount of Ga is also low, so that the crystal growth is caused to cease after some time. To address this, the seed substrate 9 is immersed again into the mixed melt 101 as shown in FIG. 2, and the seed substrate 9 is removed from the mixed melt 101 to thereby intermittently supply the mixed melt 101 containing Ga to the depression 4. The FFC method is continued until the depression 4 is filled by the growth of the buried layer 5. This enables growth of crystals with a flat c-plane.

### 1-3-3. Thickening Step S3

As shown in FIG. 1, the planarization step S2 is followed by the thickening step S3. The thickening step S3 is a step to form a planar layer 6, which is formed of a thickened GaN single crystal, on the GaN substrate (seed substrate 9) by immersing the GaN substrate serving as a seed substrate 9 with a planarized crystal surface formed in the step S2, in a mixed melt 101 including Ga and Na and stored in a crucible 100.

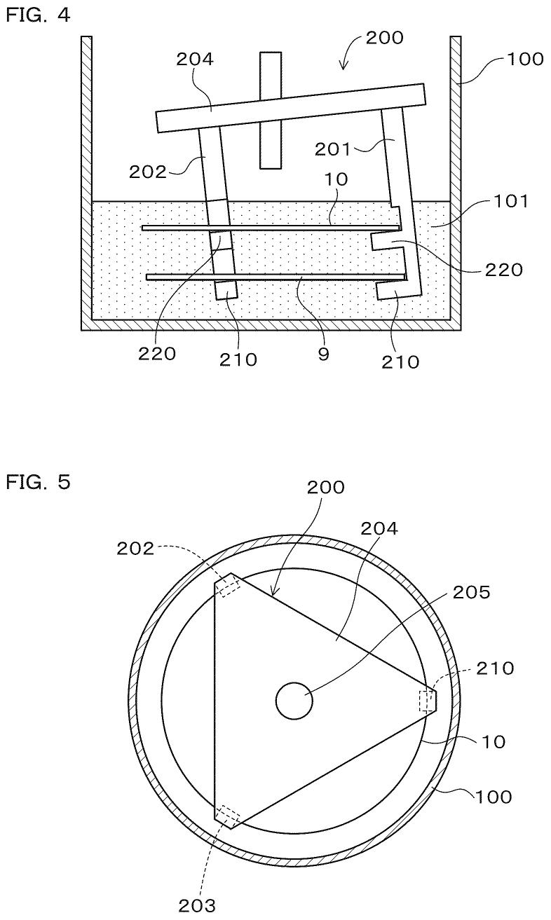

In the thickening step S3 in Embodiment 1, as shown in FIG. 4, the seed substrate having a planarized crystal surface is immersed into the mixed melt 101 while being supported by the substrate supporting part 210, and the alumina plate 10 is immersed into the mixed melt 101 while being supported by the addition feeding part 220. Here, because the alumina plate 10 contains Ca as described above, Ca dissolved from the alumina plate 10 is added to the mixed melt 101 in the thickening step S3. Thus, in Embodiment 1, the addition feeding step is performed together with the thickening step S3. As a result, the Ca included in the mixed melt 101 in the thickening step S3 promotes the lateral growth of the planar layer 6 of GaN.

In the meantime, the content ratio of Ca in the mixed melt 101 is less than 0.05 mol % in the thickening step S3, and in the initial nuclei forming step S1 and the planarization step S2, it is even lower. As a result, formation of miscellaneous crystals other than the planar layer 6 of GaN is curtailed in each step. In the case of using a crucible 10 having a large capacity, Ca may be added directly to the mixed melt 101 so that the Ca content ratio in the mixed melt 101 is less than 0.05 mol %, instead of immersing the alumina plate 10 in the mixed melt 101 in the thickening step S3.

When the planar layer 6 has grown to the desired thickness, the temperature is lowered to room temperature and the pressure is also lowered to normal pressure to terminate the growth of the planar layer 6. The duration of the thickening step S3 can be set appropriately according to the desired thickness of the planar layer 6. Here, the gap between the initial nucleus 3 and the substrate 1 remains unfilled. Therefore, the substrate 1 can be spontaneously peeled off when the temperature is lowered due to the difference in thermal expansion coefficients.

As mentioned above, according to the method of growing a GaN single crystal in Embodiment 1, the side surface of the seed crystal 2 is composed of (10-11) planes. Therefore, variation in the shape of initial nuclei 3 can be curtailed and a uniform and high-quality planar layer 6 can be formed.

In addition, the seed crystal 2 is provided with the recess 2d in the center and with no upper surface. Therefore, during the growth of the initial nucleus 3, the top of the seed crystal 2 is not filled and the voids 7 are formed. As a result, the upward propagation of dislocations in the seed crystal 2 can be curtailed, which makes it possible to form high-quality planar layer 6 to be formed.

The planarization step S2 in this embodiment, which is based on the FFC method, does not necessarily need to be performed, but it is preferable to perform the planarization step S2 in order to further improve the crystal planarity and reduce warpage more.

### 1-4. Operational Advantage

The operational advantage in the method of growing a group III nitride single crystal in this embodiment is described below. According to the method of this embodiment 1, no alkali metal nor alkaline earth metal other than Na is contained in the mixed melt 101 in the initial nuclei forming step S1. Therefore, generation of miscellaneous crystals is curtailed when forming the initial nucleus 3, so that the initial nucleus 3 can be formed with high precision as intended. In the meantime, in the thickening step S3, alkali metals or alkaline earth metals other than Na are contained in the mixed melt 101. In other words, in addition to Na, any elements among alkali metals and alkaline earth metals are contained in the mixed melt 101. It is noted that the elements can be one or more than one. As a result, the planar layer 6 of the group III nitride is encouraged to grow laterally from the initial nucleus 3, which curtails formation of macrosteps to prevent formation of inclusions. Thus, the planar layer 6 of group III nitride can be improved in the crystal quality.

According to this Embodiment 1, the alumina plate 10, which is a member containing alkali metals or alkaline earth metals other than Na, is immersed into the mixed melt 101 in the thickening step S3, to thereby elute the alkali metals or alkaline earth metals other than Na from the alumina plate 10 into the mixed melt 101. This makes it easy to add a small amount of alkali metals or alkaline earth metals other than Na to the mixed melt 101 in the thickening step S3.

According to this Embodiment 1, the alumina plate 10, which is a member containing alkali metals or alkaline earth metals other than Na, is not immersed into the mixed melt 101 in the planarization step S2. This prevents formation of miscellaneous crystals in the planarization step S2 to thereby improve the crystal quality.

In the planarization step S2, as shown in FIG. 4, the alumina plate 10, which is a member containing alkali metals or alkaline earth metals other than Na, may be immersed into the mixed melt 101 to thereby elute the alkali metals or alkaline earth metals other than Na from the alumina plate 10 into the mixed melt 101. In this case, the wettability of the mixed melt to the seed substrate 9 in the planarization step S2 can be improved to promote planarization of the crystal surface.

In this Embodiment 1, the member containing alkali metals or alkaline earth metals other than Na is the alumina plate 10, a member made of alumina containing the alkali metals or alkaline earth metals other than Na. Having such a configuration, the alumina plate 10 containing alkali metals or alkaline earth metals other than Na can gently elute the alkali metals or alkaline earth metals other than Na by immersion in the mixed melt 101, which makes it easy to add a small amount of the alkali metals or alkaline earth metals other than Na to the mixed melt 101 in the thickening step S3.

In Embodiment 1, the seed substrate 9 is supported by a jig 200 and is configured to be immersed in the mixed melt 101 and pulled up therefrom via the jig 200, and the alumina plate 10, which is a member containing alkali metals or alkaline earth metals other than Na, is supported by the addition feeding part 220 of the jig 200. In this way, the jig 200 makes it easy to control whether or not to add the alkali metals or alkaline earth metals other than Na to the mixed metal.

Embodiment 1 includes an addition feeding step of adding alkali metals or alkaline earth metals other than Na to the mixed melt 101 together with the thickening step S3. Such a configuration makes it easy to prevent the mixed melt from containing the alkali metals or alkaline earth metals other than Na in the initial nuclei forming step and to make the mixed melt contain the alkali metals or alkaline earth metals other than Na in the thickening step.

In Embodiment 1, the alkali metals or alkaline earth metals other than Na is mixed in the mixed melt 101 at a ratio of 0.01 mol % or more and less than 0.05 mol % in the thickening step S3. Due to such a configuration, the ratio of the alkali metals or alkaline earth metals other than Na contained in the mixed melt 101 in the thickening step S3 is extremely low, thus the formation of inclusions can be prevented and at the same time the formation of miscellaneous crystals can be prevented.

The jig 200 of Embodiment 1 is configured so that the first state in which the seed substrate 9 supported by the substrate supporting part 210 is immersed into the mixed melt 101 stored in the crucible 100 but the addition feeding part 220 is not immersed into the mixed melt 101 and the second state in which the seed substrate 9 supported by the substrate supporting part 210 and the addition feeding part 220 are both immersed into the mixed melt 101 can be switched to each other. This makes it easy, when the seed substrate 9 is immersed in the mixed melt 101, to set a state in which no alkali metal nor alkaline earth metal other than Na is added to the mixed melt 101 from the addition feeding part 220 in the initial nuclei forming step S1, and to set to a state in which alkali metals or alkaline earth metals other than Na is added to the mixed melt 101 in the thickening step S3. As a result, the crystal quality of the planar layer 6 can be improved.

In this embodiment, the addition feeding part 220 of the jig 200 holds the alumina plate 10, which is a member containing alkali metals or alkaline earth metals other than Na, and allows the alumina plate 10 to elute the alkali metals or alkaline earth metals other than Na to the mixed melt 101 in the second state. This makes it easy to switch the first state in which no alkali metal nor alkaline earth metal other than Na is contained in the mixed melt 101 and the second state in which alkali metals or alkaline earth metals other than Na is contained in the mixed melt 101.

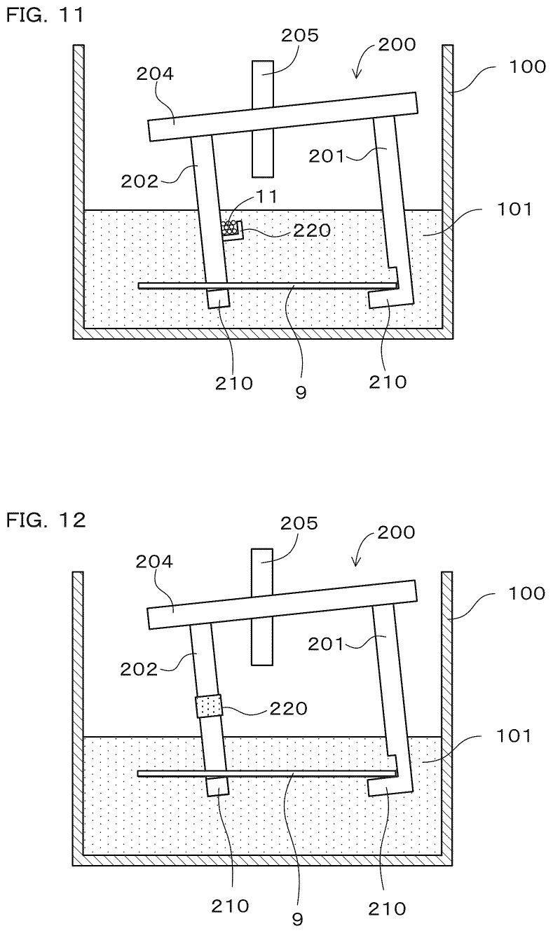

In this embodiment, as shown in FIG. 4, the jig 200 is configured to support the alumina plate 10 at the addition feeding part 220 so that the alkali metals or alkaline earth metals other than Na is added to the mixed melt 101 from the alumina plate 10 in the thickening step S3. Instead of this configuration, the jig 200 may hold alumina powder 11 containing the alkali metals or alkaline earth metals other than Na at the addition feeding part 220 as shown in FIG. 10 to add the alkali metals or alkaline earth metals other than Na from the alumina powder 11 held at the addition feeding part 220 that is immersed into the mixed melt 101 in the thickening step S3, as shown in FIG. 11. In the case of using a crucible 100 having a large capacity, alkali metals or alkaline earth metals other than Na may be added directly to the mixed melt 101 so that the Ca content ratio in the mixed melt 101 in the thickening step S3, instead of adding the alkali metals or alkaline earth metals other than Na from the alumina powder 11.

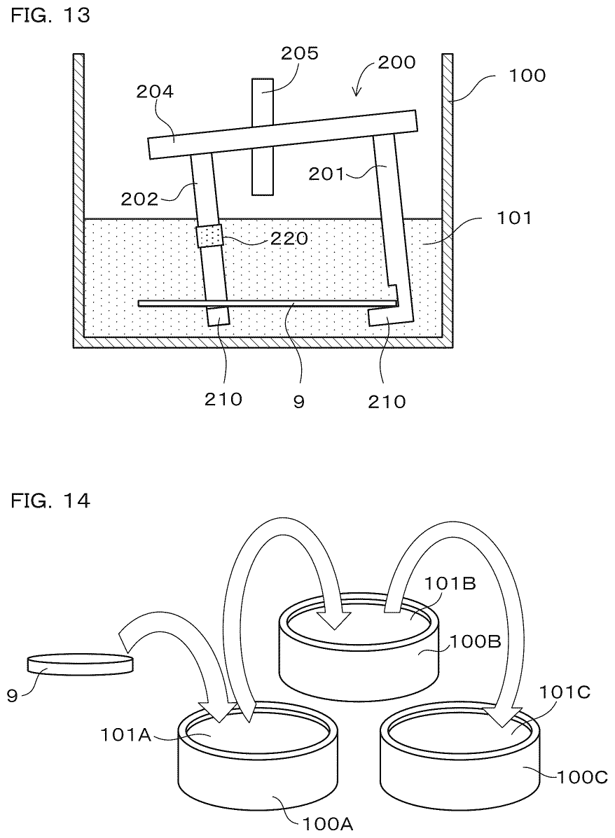

In addition, in the same way as in Modification 2 shown in FIG. 12, the addition feeding part 220 may be configured by forming part of the second leg 202 of the jig 200 with an alumina material containing alkali metals or alkaline earth metals other than Na. In Modification 2, as shown in FIG. 13, the alkali metals or alkaline earth metals other than Na may be added from the alumina material constituting the addition feeding part 220 that is immersed into the mixed melt 101 in the thickening step S3.

Although not shown in the figure, instead of the jig 200 being equipped with the addition feeding part 220, an addition feeding step may be performed, in which an alumina material containing alkali metals or alkaline earth metals other than Na is fed into the mixed melt 101 during the time after the initial nuclei forming step S1 and before the thickening step S3.

As described above, the present embodiment and the modification makes it possible to provide a method of growing a group III nitride single crystal and a jig 200 for use in growing a group III nitride single crystal that can improve the crystal quality.

### Embodiment 2

### 2-1. Overview of Embodiment 2

Similar to Embodiment 1. Embodiment 2 is a method of a growing group III nitride single crystal by the flux method. Embodiment 2 is particularly suitable for growing GaN.

In Embodiment 2, the alkali metal serving as a flux is usually sodium (Na), however, potassium (K) may also be used, or a mixture of Na and K may be used.

In Embodiment 2, calcium (Ca) is added to a mixed melt according to the manufacturing stage, as described below. In addition, three types of crucibles are prepared to hold the mixed melt, each made of a different material depending on the manufacturing stage, as described below.

### 2-2. Structure of Seed Substrate

In Embodiment 2, a seed substrate 9 is used as in Embodiment 1. The configuration of the seed substrate 9 is the same as in Embodiment 1, and a multipoint seed (MPS) substrate is used.

Embodiment 2 is particularly effective when the diameter D1 of the seed crystal 2 is small, for example, 150 μm or less, especially 100 μm or less. Although a smaller diameter of the seed crystal 2 makes it easier to separate a substrate 1 after completion of the growth of group III nitride semiconductors, the rate of nucleation from the seed crystal 2 is reduced, which causes variations in the timing of generation of initial nuclei 3. This is because the smaller seed crystal 2 has the less exposed surface on which initial nuclei is easily generated. Therefore, when the diameter D1 of each seed crystal 2 is small, it was difficult to align the shape and size of the initial nuclei 3. However, according to Embodiment 2, the shape and size of the initial nuclei 3 can be aligned even when the diameter D1 of each seed crystal 2 is small.

### 2-3. Crucibles to be Used

The method of growing a group III nitride single crystal in Embodiment 2 has an initial nuclei forming step S1, a planarization step S2, and a thickening step S3, as in Embodiment 1. Here, three types of crucibles are used to hold the mixed melt, which are made of different materials for the initial nuclei forming step S1, the planarization step S2, and the thickening step S3, respectively. Hereinafter, the crucible used in the nuclei forming step S1 is referred to as a first crucible 100A and the mixed melt held in the first crucible 100A is referred to as a mixed melt 101A. The crucible used in the planarization step S2 is referred to as a second crucible 100B, and the mixed melt held in the second crucible 100B is a mixed melt 101B. The crucible used in the thickening step S3 is referred to as third crucible 100C, and the mixed melt held in the third crucible 100C is referred to as a mixed melt 101C.

The first crucible 100A is made of Ca-free alumina. Here, the term “Ca-free” includes a concentration at and below the detection limit for Ca by general elemental analysis methods. The same applies hereinafter. Specifically, the Ca concentration is 0.001 mol % or less. When the mixed melt 101A which contains no Ca is held in the first crucible 100A which is made of such Ca-free material, the mixed melt 101A contains no Ca.

The second crucible 100B is made of alumina containing Ca. The term “containing Ca” includes a concentration higher than the detection limit for Ca by general elemental analysis methods. Specifically, the Ca concentration is higher than 0.001 mol %. The same applies hereinafter. For example, a Ca concentration of the alumina is higher than 0.001 mol % and less than 0.1 mol %. When the mixed melt 101B is held in the second crucible 100B made of such a Ca-containing material, Ca dissolves from the second crucible 100B into the mixed melt 101B to be contained in the mixed melt 101B. The second crucible 100B made of alumina containing Ca can be formed by cast molding using a plaster mold.

The third crucible 100C is made of alumina containing Ca. For example, a Ca concentration of the alumina is 0.05 to 0.5 mol %. As in the case of using the second crucible 100B, the mixed melt 101C will contain Ca when the third crucible 100C is used. The Ca concentration of alumina in the third crucible 100C is preferably set to be higher than the Ca concentration in the second crucible 100B. The concentration of Ca in the mixed melt 101C can be higher than the Ca concentration of the mixed melt 101B, which makes it possible to grow a group III nitride semiconductor of high-quality.

### 2-4. Details of the Method of Growing a Group III Nitride Single Crystal

Next, the method of growing a group III nitride single crystal in Embodiment 2 will be described with reference to the figures. As shown in FIG. 1, the method of growing a group III nitride single crystal in Embodiment 1 has an initial nuclei forming step S1, a planarization step S2, and a thickening step S3.

### 2-4-1. Initial Nuclei Forming Step

First, the initial nuclei forming step S1 is performed as in Embodiment 1. The furnace atmosphere is replaced with inert gas, the furnace is heated, and then vacuumed to sufficiently reduce outgas components such as oxygen in the furnace.

Then, a predetermined amount of alkali metal and group III metal are weighed in a glove box having an atmosphere such as oxygen and dew point controlled. The weighed predetermined amounts of the alkali metal and the group III metal are then put into the first crucible 100A, the second crucible 100B, and the third crucible 100C, respectively. If necessary, any additives such as carbon may be fed. The proportions of the alkali metal and the group III metal are the same in the first crucible 100A, second crucible 100B, and third crucible 100C, respectively.

Then, the first crucible 100A, second crucible 100B, and third crucible 100C, in which raw materials are arranged respectively, and the seed substrate 9 are placed in a reaction vessel and evacuated, and then gas containing nitrogen is supplied to the reaction vessel. Once the pressure in the reaction vessel reaches the crystal growth pressure, the furnace is heated to the crystal growth temperature. The crystal growth temperature is, for example, 700° C. or higher and 1000° C. or lower, and the crystal growth pressure is, for example, between 2 MPa or higher and 10 MPa or lower. In the process of raising the temperature, the solid alkali metals and solid group III metals in the first crucible 100A, second crucible 100B, and third crucible 100C melt and become liquid, forming a mixed melt 101A to 101C. At this stage, the seed substrate 9 is not yet put into the mixed melt 101A.

Next, once the inside of the reaction vessel reaches the crystal growth temperature and pressure and the nitrogen dissolved in the mixed melt 101A becomes supersaturated, the seed substrate 9 is put into the mixed melt 101A in the first crucible 100A, as shown in FIG. 14. Then, a group III nitride semiconductor crystal (initial nucleus 3) is generated and grows from each seed crystal 2 of the seed substrate 9. The initial nucleus 3 grows in a form of a truncated regular hexagonal pyramid or a regular hexagonal pyramid. Growth of the initial nuclei 3 continues until the initial nuclei 3 adjacent to each other begin to coalesce with each other (see (b) in FIG. 6). A gap remains between the initial nuclei 3 and the substrate 1.

Here, because the first crucible 100A is made of alumina that contains no Ca, the mixed melt 101A also contain no Ca. By making the mixed melt 101A Ca-free, it becomes easy to shape the initial nucleus 3 into a hexagonal pyramid or a truncated hexagonal pyramid, and the shape and size of the initial nucleus 3 can be further uniformed.

The (10-11) plane that the outer peripheral surface 2a of the truncated regular hexagonal pyramid portion of the seed crystal 2 has is stable in the mixed melt 101A without being etched. The height H1 of the seed crystal 2 is 30 μm or more, and the outer peripheral surface 2a has a sufficiently large area. Therefore, the initial nucleus 3 grows from the outer peripheral surface 2a, maintaining the (10-11) plane. Because the shapes of the seed crystal 2 are uniformly aligned, and the initial nucleus 3 grows from each seed crystal 2 uniformly by maintaining the (10-11) plane, variation in the shape of the initial nuclei 3 can be curtailed. As a result, the shape of each initial nucleus 3 can be uniformed.

Because a recess 2d is formed in the center of the seed crystal 2, the initial nucleus 3 does not fill the recess 2d completely and a void is formed. The mixed melt 101A is trapped inside the void. Because the void is formed in the upper part of the seed crystal 2, dislocations in the seed crystal 2 are prevented from being succeeded upward.

In addition, the diameter of the recess 2d is made larger so that the seed crystal 2 has no upper surface (c-face). C-face may be etched in the mixed melt 101A, thus is not stable. Because there is no crystal growth from such an unstable surface, the variation in the shape of the initial nuclei 3 can be further curtailed. In addition, because there is no crystal growth from the c-plane, the upward succession of dislocations in the seed crystal 2 to the top can be further suppressed.

### 2-4-2. Planarization Step

Next, the planarization step S2 is performed. The planarization step S2 is the same step as in Embodiment 1. Once the initial nuclei 3 adjacent to each other begin to coalesce with each other, the seed substrate 9 is removed from the first crucible 100A and the seed substrate 9 is put into the mixed melt 101B held in the second crucible 100B, as shown in FIG. 14. In this way, the initial nuclei forming step S1 shifts to the planarization step S2.

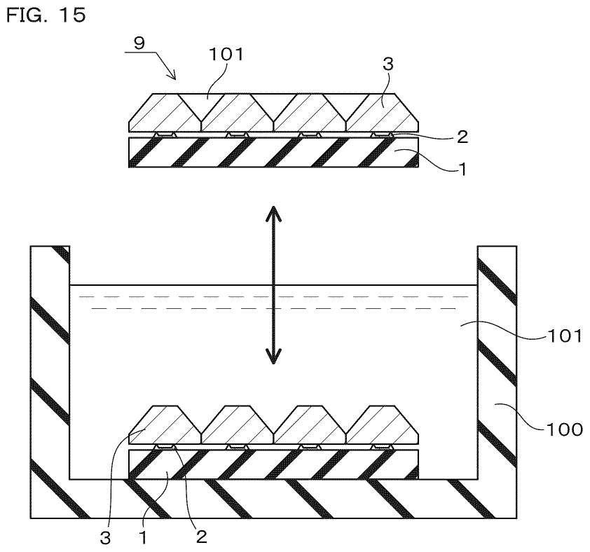

In the planarization step S2, crystals are grown using the flux film coating (FFC) method. In the FFC method, a process in which the seed substrate 9 is pulled up from the mixed melt 101B and put into the mixed melt 101B is repeatedly performed at a predetermined cycle, as shown in FIG. 15. At the stage where the initial nuclei 3 adjacent to each other begin to coalesce with each other, a depression 4 is formed on the coalesced surfaces. When the seed substrate 9 is removed from the mixed melt 101B, the mixed melt 101B accumulates in the depressions 4 between the adjacent initial nuclei 3. This allows a buried layer 5 to grow along the depression 4 (see (c) in FIG. 6).

Here, because the mixed melt 101B accumulated in the depression 4 is thin in thickness, nitrogen tends to supersaturate. Thus, the crystal growth rate can be accelerated.

However, because the amount of the accumulated mixed melt 101B is small, the amount of the group III metal is also low, so that the crystal growth is caused to cease after some time.

To address this, the seed substrate 9 is immersed again into the mixed melt 101 and is removed from the mixed melt 101 to thereby intermittently supply the mixed melt 101 containing the group III metal to the depression 4. The FFC method is continued until the depression 4 is filled by the growth of the buried layer 5. This enables growth of crystals with a flat c-plane.

In the planarization step S2, Ca is dissolved from the second crucible 100B into the mixed melt 101B because the second crucible 100B is made of alumina containing Ca. As a result, the mixed melt 101B contains Ca. Because the mixed melt 101B contains Ca, the wettability of the mixed melt 101B is improved, and thus the crystallinity of the buried layer 5 can be improved. The Ca concentration of the mixed melt 101B is preferably 0.001 to 0.1 mol %. By setting the Ca concentration within such a range, the crystallinity of the buried layer 5 can be further improved and miscellaneous crystals can be curtailed.

In the planarization step S2, it is not necessary to form the buried layer 5 by the FFC method, however, it is preferable to use the FFC method to further improve the crystal planarity and reduce warpage more.

### 2-4-3. Thickening Process

Next, the thickening step S3 is performed. The thickening step S3 is the same process as in Embodiment 1. When the depression 4 is filled with the buried layer 5 to form a planarized crystal surface, the seed substrate 9 is removed from the second crucible 100B and is put into the mixed melt 101C held in the third crucible 100C, as shown in FIG. 14. In this way, the planarization step S2 shifts to the thickening step S3.

In the thickening step S3, the seed substrate 9 is put into the mixed melt 101C to grow the planar layer 6 and thicken the same on the planarized crystal surface (see (d) in FIG. 6). The planar layer 6 is made of a group III nitride semiconductor with a flat surface.

Because the shape of each initial nucleus 3 is uniformed, the planar layer 6 can also be formed uniformly in the plane. In addition, because the upward succession of dislocations in the seed crystal 2 is curtailed, the planar layer 6 can be formed so as to have high quality.

In the thickening step S3, Ca is dissolved from the third crucible 100C into the mixed melt 101C because the third crucible 100C is made of alumina containing Ca. As a result, the mixed melt 101C contains Ca. Because the mixed melt 101C contains Ca, the wettability of the mixed melt 101C is improved, and thus macrostep growth of the group III nitride semiconductor can be curtailed. As a result, the crystallinity of the planar layer 6 can be improved. In this case, the Ca concentration of the mixed melt 101C in the thickening step S3 is preferably set to be higher than that of the mixed melt 101B in the planarization step S2.

The Ca concentration is preferably 0.001 to 0.1 mol %. However, in terms of preventing miscellaneous crystal, the Ca concentration in the thickening step S3 is preferably 0.05 mol % or less.

Once the planar layer 6 has grown to the desired thickness, the seed substrate 9 is removed from the third crucible 100C, and thereafter the temperature is lowered to room temperature and the pressure is also lowered to normal pressure to terminate the growth of the group III nitride semiconductor. Here, the gap between the initial nucleus 3 and substrate 1 remains unfilled. Therefore, the substrate 1 can be spontaneously peeled off from the grown crystal when the temperature is lowered due to the difference in thermal expansion coefficients. In particular, when the diameter D1 of the seed crystal 2 is 150 μm or less, the substrate 1 can be peeled off more easily.

As described above, three types of crucibles with different Ca contents are used in the method of growing a group III nitride single crystal in Embodiment 2, that is a first crucible 100A, a second crucible 100B, and a third crucible 100C. This allows the mixed melt 101A to be Ca-free in the initial nuclei forming step S1, and allows the mixed melt 101B and 101C to contain Ca in the planarization step S2 and the thickening step S3. As a result, a group III nitride semiconductor crystal of good quality can be grown.

Since different crucibles are used for the initial nuclei forming step S1, the planarization step S2, and the thickening step S3, depletion of raw materials such as Ga can be prevented.

### 2-5. Manufacturing Apparatus in Embodiment 2

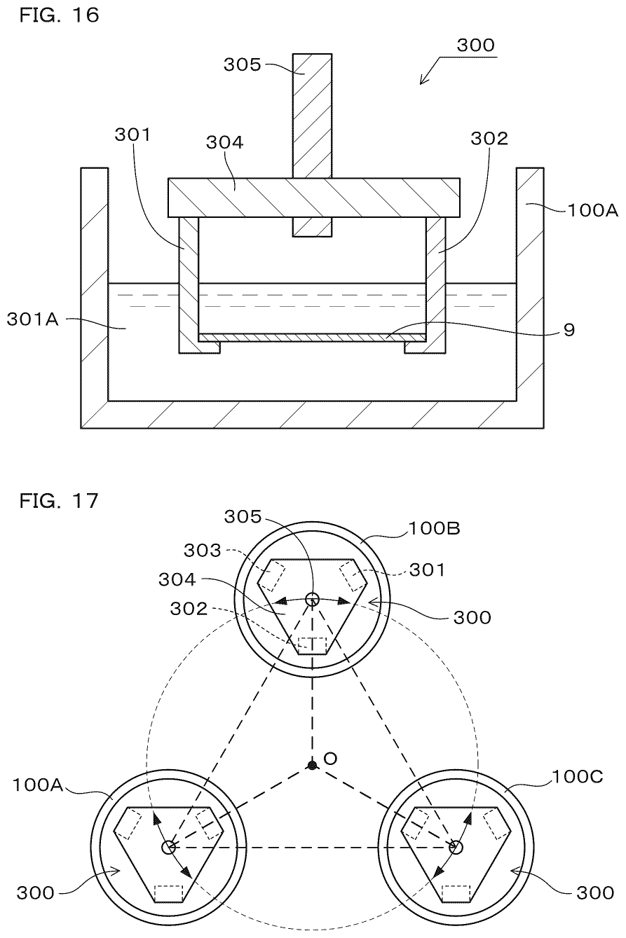

The apparatus for manufacturing a group III nitride single crystal in Embodiment 2 will be described. FIGS. 16 and 17 show the configuration of the manufacturing apparatus for a group III nitride single crystal. The manufacturing apparatus for a group III nitride semiconductor in Embodiment 2 can be suitably used, for example, for the method of forming a group III nitride single crystal in Modification 4 of Embodiment 2, which will be described below.

The apparatus for manufacturing a group III nitride single crystal in Embodiment 2 includes three jigs 300. FIG. 16 is schematic view showing a configuration of a jig 300 in the apparatus for manufacturing a group III nitride single crystal in Embodiment 2. FIG. 17 is a plan view vertically viewed from above, showing the relation between the arrangement of the first crucible 100A, the second crucible 100B, and the third crucible 100C and the arrangement of the three jigs 300 in Embodiment 2.

The three jigs 300 are placed in the reaction vessel along with the first crucible 100A, the second crucible 100B, and the third crucible 100C. As shown in FIGS. 16 and 17, the jigs 300 each include a first leg 301, a second leg 302, a third leg 303, a connecting portion 304, and an elevating shaft 305. Each component of the jigs 300 is made of alumina. The first leg 301, the second leg 302, and the third leg 303 are formed in an abbreviated rod shape, and hang down respectively at the corners of the flat connecting portion 304 of an almost triangular shape in plan view as shown in FIG. 12.

At each lower end of the first leg 301, the second leg 302, and the third leg 303, a convex portion capable of supporting the seed substrate 9 is formed. The connecting portion 304 is connected to the elevating shaft 305. The elevating shaft 305 is configured to move up and down in the vertical direction. This makes it possible for the seed substrate 9 supported by the first leg 301, the second leg 302, and the third leg 303 to be put into and removed from the crucible. The elevation shaft 305 of the three jigs 300 can be moved up and down independently of each other.

The three jigs 300 are arranged to form an equilateral triangle in plan view, as shown in FIG. 17. The outer center of this equilateral triangle is hereinafter referred to as point O.

The first crucible 100A, the second crucible 100B, and the third crucible 100C are arranged to form an equilateral triangle so as to face the three jigs 300 respectively. The three jigs 300 are configured to rotate about the point O. By rotating the three jigs 300 in this manner, one jig 300 can be moved to face any of the first crucible 100A, the second crucible 100B, and the third crucible 100C.

When a certain jig 300 and the first crucible 100A are facing each other, the seed substrate 9 can be controlled to be immersed into the mixed melt 101A that is held in the first crucible 100A and removed therefrom by moving the elevating shaft 305 of the jig 300 up and down to thereby move the seed substrate 9 held by the jig 300. The seed substrate 9 can also be controlled to be immersed into the mixed melt 101B that is held in the first crucible 100B and removed therefrom, and to be immersed into the mixed melt 101C that is held in the third crucible 100C and removed therefrom. These controls can be performed independently.

As described above, by using the apparatus for manufacturing a group III nitride single crystal in Embodiment 2, the method for manufacturing a group III nitride semiconductor in Modification 4 of Embodiment 1 can be easily realized.

Although Embodiment 2 is a case where three jigs 300 are used, this embodiment can be applied in the same manner to a case where two jigs 300 are used and a case where four or more jigs 300 are used. In fact, it is only required to arrange a plurality of jigs 300 at equal intervals on a circumference in a plan view so as to be rotatable integrally about the center of the circumference.

### Modification 1 of Embodiment 2

In Embodiment 2, the mixed melt 101B contains Ca in the planarization step S2, however, the mixed melt 101B may not contain Ca. In this case, the second crucible 100B may be made of alumina that does not contain Ca.

### Modification 2 of Embodiment 2

In Embodiment 2, three types of crucibles, i.e. the first crucible 100A, the second crucible 100B, and the third crucible 100C are used. However, it is also possible to use the first crucible 100A and the third crucible 100C, and to use either the first crucible 100A or the third crucible 100C in the planarization step S2. Thus, the number of crucibles to be used can be reduced to thereby grow a group III nitride semiconductor more simply.

### Modification 3 of Embodiment 2

In Embodiment 2, the Ca contents of the mixed melts 101A, 101B, and 101C are respectively changed by changing the Ca contents in the three types of crucibles (the first crucible 100A, the second crucible 100B, and the third crucible 100C), respectively.

However, the Ca contents of the mixed melts 101A, 101B, and 101C may be changed by other methods.

For example, the first crucible 100A, the second crucible 100B, and the third crucible 100C may be made of Ca-free alumina, and the amount of Ca to be added to the first crucible 100A, the second crucible 100B, and the third crucible 100C may be changed at the time of preparing raw materials to thereby change the Ca contents of the mixed melts of 101A, 101B, and 101C, respectively. Alternatively, solid Na or solid Ga with different Ca content may be used as a raw material to thereby change the Ca content of the mixed melts 101A, 101B, and 101C.

### Modification 4 of Embodiment 2

It is also possible to use three seed substrates 9 and rotate the initial nuclei forming step S1, the planarization step S2, and the thickening step S3 to thereby grow a group III nitride semiconductor respectively on the three seed substrates 9 in one production process.

Specifically, after the initial nuclei forming step S1 is completed for the first seed substrate 9, the second seed substrate 9 is put into the first crucible 100A to perform the initial nuclei forming step S1 and the first seed substrate 9 is put into the second crucible 100B to perform the planarization step S2. After the planarization step S2 is completed for the first seed substrate 9 and the initial nuclei forming step S1 is completed for the second seed substrate 9, the third seed substrate 9 is put into the first crucible 100A to perform the initial nuclei forming step S1, the second seed substrate 9 is put into the second crucible 100B to perform the planarization step S2, and the first seed substrate 9 is put into the third crucible 100C to perform the thickening step S3. Hereafter, by performing such rotations in the same manner, group, a III nitride single crystal can be grown on the three seed substrates 9, respectively.

### Modification 5 of Embodiment 2

A fourth crucible made of alumina that contains calcium may be prepared to perform a further planarization step using the fourth crucible after performing the planarization step for a predetermined time using the third crucible 100C. The thickening step S3 tends to deplete raw materials such as Ga because the planar layer 6 is thickened. Therefore, the use of the fourth crucible can prevent the depletion of raw materials. Of course, fifth and sixth crucibles may be prepared to repeat these steps in the same manner. As in Modification 3, a fourth crucible made of calcium-free alumina may be used, and the mixed melt containing calcium may be held in the fourth crucible.

The present disclosure is not limited to the above-described embodiments and modifications, and can be applied to various embodiments to the extent not departing from the gist thereof.

What is claimed is:

1. A method of growing a group III nitride single crystal, the method comprising:
immersing a seed substrate, on which a plurality of seed crystals each made of a group III nitride single crystal is formed, into a mixed melt including a group III metal and Na and stored in a crucible to grow a group III nitride single crystal from each seed crystal to thereby form a plurality of initial nuclei;
repeatedly performing a process in which the seed substrate having the plurality of initial nuclei formed thereon is immersed into a mixed melt stored in a crucible and is pulled up from the crucible after the immersion and heated under a nitrogen atmosphere to grow the group III nitride single crystal from the initial nuclei and fill a gap between the initial nuclei adjacent to each other with the group III nitride single crystal to thereby form a planarized crystal surface; and
immersing the seed substrate having the planarized crystal surface into a mixed melt stored in a crucible to thereby form a thickened group III nitride single crystal on the seed substrate, wherein
when forming the plurality of initial nuclei, a concentration of alkali metals or alkaline earth metals other than Na in the mixed melt is set to 0.001 mol % or less, and
when forming the thickened group III nitride single crystal, a concentration of alkali metals or alkaline earth metals other than Na in the mixed melt is set higher than that when forming the plurality of initial nuclei.

2. The method according to claim 1, wherein when forming the plurality of initial nuclei, the concentration of alkali metals or alkaline earth metals other than Na in the mixed melt is set to 0 mol %.

3. The method according to claim 1, wherein when forming the thickened group III nitride single crystal, a member containing alkali metals or alkaline earth metals other than Na is immersed into the mixed melt to thereby elute the alkali metals or alkaline earth metals other than Na from the member into the mixed melt, and
when forming the plurality of initial nuclei, the member containing alkali metals or alkaline earth metals other than Na is not immersed in the mixed melt.

4. The method according to claim 3, wherein when forming the planarized crystal surface, the member containing alkali metals or alkaline earth metals other than Na is immersed in the mixed melt to thereby elute the alkali metal or alkaline earth metal other than Na from the member into the mixed melt.

5. The method according to claim 3, wherein when forming the planarized crystal surface, the member containing alkali metals or alkaline earth metals other than Na is not immersed in the mixed melt.

6. The method according to claim 3, wherein the member containing alkali metals or alkaline earth metals other than Na is made of alumina containing alkali metals or alkaline earth metals other than Na.

7. The method according to claim 6, wherein the seed substrate is supported by a jig and is configured to be immersed in the mixed melt and pulled up therefrom via the jig, and
the member containing alkali metals or alkaline earth metals other than Na constitutes part of the jig or is supported by the jig.

8. The method according to claim 1, wherein the alkali metals or alkaline earth metals other than Na are added to the mixed melt at a time after forming the plurality of initial nuclei and before forming the thickened group III nitride single crystal, or at a time of forming the thickened group III nitride single crystal.

9. The method according to claim 1, wherein when forming the thickened group III nitride single crystal, the alkali metals or alkaline earth metals other than Na is mixed in the mixed melt at a ratio of 0.01 mol % or more and less than 0.05 mol %.

10. The method according to claim 1, wherein when forming the plurality of initial nuclei, a calcium concentration of the mixed melt is adjusted to be 0.001 mol % or less by use of a first crucible made of alumina having a calcium concentration of 0.01 mol % or less to hold the mixed melt therein, and
when forming the thickened group III nitride single crystal, the calcium concentration of the mixed melt is adjusted to be higher than 0.001 mol % by use of a second crucible made of alumina having a calcium concentration higher than 0.01 mol % to hold the mixed melt therein.

11. The method according to claim 1, wherein when forming the plurality of initial nuclei, the first crucible made of alumina having a calcium concentration of 0.01 mol % or less is used to hold the mixed melt of which the calcium concentration is 0.001 mol % or less, and
when forming the thickened group III nitride single crystal, the second crucible made of alumina is used to hold the mixed melt of which the calcium concentration is higher than 0.001 mol %.

12. The method according to claim 10, wherein when forming the planarized crystal surface, a calcium concentration of the mixed melt is adjusted to be 0.001 mol % or higher by use of a third crucible made of alumina having a calcium concentration of 0.01 mol % or higher to hold the mixed melt therein, and
when forming the thickened group III nitride single crystal, the calcium concentration of the mixed melt is higher than that when forming the planarized crystal surface.

13. The method according to claim 10, wherein when forming the planarized crystal surface, a third crucible made of alumina is used to hold the mixed melt of which the calcium concentration is higher than 0.001 mol %, and
when forming the thickened group III nitride single crystal, the calcium concentration of the mixed melt is higher than that when forming the planarized crystal surface.

14. The method according to claim 10, wherein when forming the planarized crystal surface, the second crucible is used.

15. The method according to claim 10, wherein when forming the thickened group III nitride single crystal, the calcium concentration of the mixed melt is adjusted to be 0.001 mol % or higher by use of a fourth crucible made of alumina having a calcium concentration of 0.01 mol % or higher to hold the mixed melt therein, and
after forming the group III nitride single crystal using the second crucible, the group III nitride single crystal is further grown using the fourth crucible.

16. The method according to claim 10, wherein when forming the thickened group III nitride single crystal, a fourth crucible made of alumina is used to hold the mixed melt of which the calcium concentration is higher than 0.001 mol %, and
after forming a planarized group III nitride single crystal using the second crucible, a further group III nitride single crystal is formed using the fourth crucible.

17. A jig for use in growing a group III nitride single crystal, configured to support a substrate for growing the group III nitride single crystal inside a crucible, the jig comprising:
a substrate supporting part configured to support the substrate and immerse the substrate into a mixed melt including a group III metal and Na and stored in a crucible; and
an addition feeding part configured to add alkali metals or alkaline earth metals other than Na into the mixed melt when the substrate is immersed in the mixed melt, wherein
a first state in which the substrate supported by the substrate supporting part is immersed into the mixed melt but the addition feeding part is not immersed and a second state in which the substrate supported by the substrate supporting part and the addition feeding part are both immersed into the mixed melt are configured to be switched to each other.

18. The jig according to claim 17, wherein the addition feeding part is configured to hold a member including alkali metals or alkaline earth metals other than Na and to elute the alkali metals or alkaline earth metals other than Na from the member including the alkali metals or alkaline earth metals other than Na to the mixed melt in the second state.

19. An apparatus for manufacturing a group III nitride single crystal, in which the group III nitride single crystal is grown on a seed substrate by supplying a gas containing nitrogen into a mixed melt including a group III metal and a flux, the apparatus comprising:
a plurality of jigs for holding the seed substrate to immerse and pull up the seed substrate in and from the mixed melt, wherein
each of the plurality of jigs is independently configured to be able to immerse and pull up the seed substrate in and from the mixed melt.

20. The apparatus according to claim 19, wherein the plurality of jibs is arranged at equal intervals on a circumference when vertically viewed from above, having a configuration to be rotatable integrally around a center of the circumference.
